(19) United States
(12) Patent Application Publication
(10) Pub. No.: US 2024/0204010 A1
(43) Pub. Date: Jun. 20, 2024

(54) Thin Film Transistor Substrate and Display Apparatus Comprising the Same

(71) Applicant: LG Display Co., Ltd., Seoul (KR)

(72) Inventors: Soyang Choi, Paju-si (KR); Youngjin Yi, Paju-si (KR); JungJune Kim, Paju-si (KR); Yubeen Lim, Paju-si (KR)

(21) Appl. No.: 18/239,708

(22) Filed: Aug. 29, 2023

(30) Foreign Application Priority Data
Dec. 14, 2022 (KR) 10-2022-0174607

(51) Int. Cl. H01L 27/12; H01L 23/552

(52) U.S. Cl. CPC H01L 27/1248; H01L 23/552; H01L 27/1225

(57) ABSTRACT

A thin film transistor substrate comprises a first thin film transistor on a base substrate, a second thin film transistor on the first thin film transistor, and a first protective pattern between the first thin film transistor and the second thin film transistor, wherein the first thin film transistor includes a first active layer on the base substrate, and a first gate electrode spaced apart from the first active layer, the second thin film transistor includes a second active layer on the base substrate, and a second gate electrode spaced apart from the second active layer, the first active layer includes a first channel portion that overlaps the first gate electrode, the second active layer includes a second channel portion that overlaps the second gate electrode, wherein the first protective pattern overlaps the second channel portion and covers the entire second channel portion on a plane.

### CROSS-REFERENCE TO RELATED APPLICATION

This application claims the benefit of Republic of Korea Patent Application No. 10-2022-0174607 filed on Dec. 14, 2022, the contents of which are hereby incorporated by reference in their entirety.

### BACKGROUND

### Field of Technology

The present disclosure relates to a thin film transistor substrate and a display apparatus comprising the same, and more particularly, to a thin film transistor substrate comprising a first thin film transistor and a second thin film transistor, which are stacked on top of each other, and a display comprising the same.

### Discussion of the Related Art

Transistors are widely used as switching devices or driving devices in the field of electronic apparatuses. In particular, since a thin film transistor can be manufactured on a glass substrate or a plastic substrate, the thin film transistor is widely used as a switching device of a display apparatus such as a liquid crystal display apparatus or an organic light emitting display apparatus.

The thin film transistor may be categorized into an amorphous silicon thin film transistor in which amorphous silicon is used as an active layer, a polycrystalline silicon thin film transistor in which polycrystalline silicon is used as an active layer and an oxide semiconductor thin film transistor in which oxide semiconductor is used as an active layer, based on a material constituting the active layer.

Since amorphous silicon may be deposited in a short time to form an active layer, an amorphous silicon thin film transistor (a-Si TFT) has advantages in that a manufacturing process time is short and a production cost is low. On the other hand, the amorphous silicon thin film transistor has a drawback in that it is restrictively used for an active matrix organic light emitting diode (AMOLED) because a current driving capacity is not good due to low mobility and there is a change in a threshold voltage.

A polycrystalline silicon thin film transistor (poly-Si TFT) is made by depositing amorphous silicon and crystallizing the deposited amorphous silicon. Since a process of manufacturing the polycrystalline silicon thin film transistor needs a step of crystallizing the amorphous silicon, a manufacturing cost is increased due to the increased number of the process steps. Since crystallization is performed at a high process temperature, it is difficult to apply the polycrystalline silicon thin film transistor to a large-sized display apparatus. Also, it is difficult to achieve uniformity of the polycrystalline silicon thin film transistor due to polycrystalline characteristics.

An oxide constituting an active layer of an oxide semiconductor thin film transistor may be grown at a relatively low temperature, and the oxide semiconductor thin film transistor has high mobility, and has a large resistance change in accordance with an oxygen content, whereby desired properties may be easily obtained. Further, in view of the properties of the oxide, since an oxide semiconductor is transparent, it is favorable to embody a transparent display. When hydrogen is permeated into the oxide semiconductor thin film transistor, reliability of the oxide semiconductor may deteriorate. Therefore, it is required to control hydrogen in the oxide semiconductor thin film transistor.

### SUMMARY

The present disclosure has been made in view of the above problems and it is an object of the present disclosure to provide a thin film transistor substrate that includes a protective pattern having hydrogen blocking characteristics to prevent or suppress hydrogen from being diffused or permeated into an active layer.

It is another object of the present disclosure to provide a display apparatus comprising a thin film transistor substrate.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor substrate comprising a first thin film transistor on a base substrate, a second thin film transistor on the first thin film transistor, and a first protective pattern between the first thin film transistor and the second thin film transistor, wherein the first thin film transistor includes a first active layer on the base substrate, and a first gate electrode spaced apart from the first active layer, the second thin film transistor includes a second active layer on the base substrate, and a second gate electrode spaced apart from the second active layer, the first active layer includes a first channel portion that overlaps the first gate electrode, the second active layer includes a second channel portion that overlaps the second gate electrode, and the first protective pattern overlaps the second channel portion and covers the entire second channel portion on a plane.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view illustrating a thin film transistor substrate according to one embodiment of the present disclosure;

FIG. 2 is a cross-sectional view illustrating a thin film transistor substrate according to another embodiment of the present disclosure;

FIG. 3 is a cross-sectional view illustrating a thin film transistor substrate according to still another embodiment of the present disclosure;

FIG. 4 is a cross-sectional view illustrating a thin film transistor substrate according to further still another embodiment of the present disclosure;

FIG. 5 is a cross-sectional view illustrating a thin film transistor substrate according to further still another embodiment of the present disclosure;

FIG. 6 is a cross-sectional view illustrating a thin film transistor substrate according to further still another embodiment of the present disclosure;

FIG. 7 is a cross-sectional view illustrating a thin film transistor substrate according to further still another embodiment of the present disclosure;

FIG. 8 is a cross-sectional view illustrating a thin film transistor substrate according to further still another embodiment of the present disclosure;

FIG. 9 is a cross-sectional view illustrating a thin film transistor substrate according to further still another embodiment of the present disclosure;

FIG. 10 is a cross-sectional view illustrating a thin film transistor substrate according to further still another embodiment of the present disclosure;

FIG. 11 is a cross-sectional view illustrating a thin film transistor substrate according to further still another embodiment of the present disclosure;

FIG. 12 is a cross-sectional view illustrating a thin film transistor substrate according to further still another embodiment of the present disclosure;

FIG. 13 is a cross-sectional view illustrating a thin film transistor substrate according to further still another embodiment of the present disclosure;

FIG. 14 is a plan view illustrating a portion of a thin film transistor substrate according to further still another embodiment of the present disclosure;

FIG. 15 is a cross-sectional view taken along line I-I′ of FIG. 14 according to one embodiment of the present disclosure;

FIG. 16 is a cross-sectional view taken along line II-II′ of FIG. 14 according to one embodiment of the present disclosure;

FIG. 17 is a schematic view illustrating a display apparatus according to one embodiment of the present disclosure;

FIG. 18 is a schematic view illustrating a shift register according to one embodiment of the present disclosure;

FIG. 19 is a circuit view illustrating any one pixel of FIG. 17 according to one embodiment of the present disclosure;

FIG. 20 is a circuit view illustrating any one pixel of a display apparatus according to further still another embodiment of the present disclosure; and

FIG. 21 is a circuit view illustrating any one pixel of a display apparatus according to further still another embodiment of the present disclosure.

### DETAILED DESCRIPTION OF THE DISCLOSURE

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are only distinguished for convenience of description, and the source electrode and the drain electrode may be interchanged. The source electrode may be the drain electrode, and the drain electrode may be the source electrode. In addition, the source electrode of any one embodiment may be the drain electrode in another embodiment, and the drain electrode of any one embodiment may be the source electrode in another embodiment.

In some embodiments of the present disclosure, for convenience of description, a source area and a source electrode are distinguished from each other, and a drain area and a drain electrode are distinguished from each other, but the embodiments of the present disclosure are not limited thereto. The source area may be the source electrode, and the drain area may be the drain electrode. In addition, the source area may be the drain electrode, and the drain area may be the source electrode.

FIG. 1 is a cross-sectional view illustrating a thin film transistor substrate 100 according to one embodiment of the present disclosure.

The thin film transistor substrate 100 according to one embodiment of the present disclosure includes a first thin film transistor T1 and a second thin film transistor T2. In addition, the thin film transistor substrate 100 according to one embodiment of the present disclosure includes a first protective pattern 161 for protecting the second thin film transistor T2.

Referring to FIG. 1, the first thin film transistor T1 is disposed on a base substrate 110, and the second thin film transistor T2 is disposed on the first thin film transistor T1.

In FIG. 1, the second thin film transistor T2 is disposed on the first thin film transistor T1 based on the base substrate 110, but one embodiment of the present disclosure is not limited thereto, and the positions of the first thin film transistor T1 and the second thin film transistor T2 may be interchanged.

The first thin film transistor T1 according to one embodiment of the present disclosure includes a first active layer 120 on the base substrate 110 and a first gate electrode 140 spaced apart from the first active layer 120 to at least partially overlap the first active layer 120.

Glass or plastic may be used as the base substrate 110. A transparent plastic having a flexible property, for example, polyimide may be used as the base substrate 110.

When polyimide is used as the base substrate 110, a heat-resistant polyimide capable of enduring a high temperature may be used considering that a high temperature deposition process is performed on the base substrate 110. In this case, in order to form the thin film transistor, a process such as deposition, etching, etc. may be performed in a state that a polyimide substrate is disposed on a carrier substrate made of a high durability material such as glass.

Although not shown in FIG. 1, a buffer layer may be disposed on the base substrate 110. The buffer layer is formed on the base substrate 110, and may be formed of an inorganic material or an organic material. For example, the buffer layer may include an insulating oxide such as silicon oxide (SiOx) and aluminum oxide (Al₂O₃).

The buffer layer serves to protect the active layer 120 by blocking impurities such as moisture and oxygen introduced from the base substrate 110 and planarize an upper portion of the base substrate 110, may be formed of as a single layer or multiple layers.

Referring to FIG. 1, the first active layer 120 is disposed on the base substrate 110. When the buffer layer is disposed on the base substrate 110, the first active layer 120 may be disposed on the buffer layer.

According to one embodiment of the present disclosure, the first active layer 120 may be formed by a semiconductor material. The first active layer 120 may include an oxide semiconductor material.

The oxide semiconductor material may include, for example, at least one of an IZO(InZnO)-based oxide semiconductor material, an IGO(InGaO)-based oxide semiconductor material, an ITO(InSnO)-based oxide semiconductor material, an IGZO(InGaZnO)-based oxide semiconductor material, an IGZTO(InGaZnSnO)-based oxide semiconductor material, a GZTO(GaZnSnO)-based oxide semiconductor material, a GZO(GaZnO)-based oxide semiconductor material, an ITZO(InSnZnO)-based oxide semiconductor material, or a FIZO(FeInZnO)-based oxide semiconductor material, but one embodiment of the present disclosure is not limited thereto. The first active layer 120 may be made of another oxide semiconductor material known in the art.

The first active layer 120 may include a first channel portion 121, a first source connection portion 122 and a first drain connection portion 123. The first source connection portion 122 may be connected to one side of the first channel portion 121, and the first drain connection portion 123 may be connected to the other side of the first channel portion 121.

The first channel portion 121 overlaps the first gate electrode 140. The first channel portion 121 may be protected by the first gate electrode 140. The first channel portion 121 serves as a channel.

The first source connection portion 122 and the first drain connection portion 123 may be formed by selective conductorization for the first active layer 120 made of a semiconductor material. According to one embodiment of the present disclosure, the case that conductivity is given to a specific portion of a semiconductor layer to allow the specific portion to serve as a conductor will be referred to as selective conductorization.

For example, the first active layer 120 may be selectively conductorized by ion doping. As a result, the first source connection portion 122 and the first drain connection portion 123 may be formed, but one embodiment of the present disclosure is not limited thereto. The first active layer 120 may be selectively conductorized by another method known in the art.

The first source connection portion 122 and the first drain connection portion 123 have excellent electrical conductivity. Therefore, each of the first source connection portion 122 and the first drain connection portion 123 may serve as a line.

A first gate insulating layer 130 may be disposed on the first active layer 120. The first gate insulating layer 130 may include at least one of silicon oxide, silicon nitride or metal oxide. The first gate insulating layer 130 may have a single-layered structure or a multi-layered structure.

A first gate electrode 140 may be disposed on the first gate insulating layer 130. The first gate electrode 140 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti).

An interlayer insulating layer 150 may be disposed on the first gate electrode 140. The interlayer insulating layer 150 is an insulating layer made of an insulating material. The interlayer insulating layer 150 may be made of an organic material, may be made of an inorganic material, or may be made of a stacked body of an organic material layer and an inorganic material layer. The interlayer insulating layer 150 may include silicon oxide, silicon nitride, metal oxide, etc.

According to one embodiment of the present disclosure, the first thin film transistor T1 may include a first source electrode 171 and a first drain electrode 172. For example, as shown in FIG. 1, the first source electrode 171 and the first drain electrode 172 may be disposed on the interlayer insulating layer 150.

The first source electrode 171 and the first drain electrode 172 may be spaced apart from each other and respectively connected to the first active layer 120. Referring to FIG. 1, each of the first source electrode 171 and the first drain electrode 172 may be connected to the first active layer 120 through a contact hole.

Each of the first source electrode 171 and the first drain electrode 172 may include at least one of molybdenum (Mo), aluminum (Al), chromium (Cr), gold (Au), titanium (Ti), nickel (Ni), neodymium (Nd), copper (Cu) or their alloy.

In one embodiment and the drawings of the present disclosure, the first source electrode 171 and the first drain electrode 172 are only distinguished for convenience of description, and the first source electrode 171 and the first drain electrode 172 are not limited by the drawings and the aforementioned descriptions. The first source electrode 171 and the first drain electrode 172 may be interchanged. The first source connection portion 122 and the first drain connection portion 123 are also distinguished for convenience of description, and the first source connection portion 122 and the first drain connection portion 123 may be interchanged.

According to one embodiment of the present disclosure, a portion of the first active layer, which is connected to the first source electrode 171, will be referred to as the first source connection portion 122, and a portion of the first active layer, which is connected to the first drain electrode 172, will be referred to as the first drain connection portion 123.

A passivation layer 180 may be disposed on the first source electrode 171 and the first drain electrode 172. The passivation layer 180 may include at least one of silicon oxide, silicon nitride and metal oxide. The passivation layer 180 may have a single-layered structure or a multi-layered structure. The passivation layer 180 protects the first thin film transistor T1.

The second thin film transistor T2 may be disposed on the passivation layer 180.

The second thin film transistor T2 according to one embodiment of the present disclosure includes a second active layer 220 on the base substrate 110 and a second gate electrode 240 spaced apart from the second active layer 220 to at least partially overlap the second active layer 220.

Referring to FIG. 1, the second active layer 220 may be disposed on the passivation layer 180. In detail, according to one embodiment of the present disclosure, a passivation layer 180 supports the second active layer 220.

According to one embodiment of the present disclosure, the second active layer 220 may be formed by a semiconductor material. The second active layer 220 may include an oxide semiconductor material.

The second active layer 220 may be made of the same oxide semiconductor material as that of the first active layer 120, or may be made of an oxide semiconductor material different from that of the first active layer 120.

The second active layer may include a second channel portion 221, a second source connection portion 222 and a second drain connection portion 223. The second source connection portion 222 may be connected to one side of the second channel portion 221, and the second drain connection portion 223 may be connected to the other side of the second channel portion 221.

The second channel portion 221 overlaps the second gate electrode 240. The second channel portion 221 serves as a channel.

A second source connection portion 222 and a second drain connection portion 223 may be formed by selective conductorization of the second active layer 220.

For example, the second active layer 220 may be selectively conductorized by ion doping. As a result, the second source connection portion 222 and the second drain connection portion 223 may be formed, but one embodiment of the present disclosure is not limited thereto, and the second active layer 220 may be selectively conductorized by another method known in the art.

The second source connection portion 222 and the second drain connection portion 223 have excellent electrical conductivity as compared with the second channel portion 221. Therefore, each of the second source connection portion 222 and the second drain connection portion 223 may serve as a line.

A second gate insulating layer 230 may be disposed on the second active layer 220.

The second gate insulating layer 230 may include at least one of silicon oxide, silicon nitride or metal oxide. The second gate insulating layer 230 may have a single-layered structure or a multi-layered structure.

The second gate electrode 240 is disposed on the second gate insulating layer 230.

The second gate electrode 240 may include a metal or a metal alloy. The second gate electrode 240 may be formed of the same material as that of the first gate electrode 140, or may be formed of a material different from that of the first gate electrode 140.

The second gate electrode 240 is spaced apart from the second active layer 220 to at least partially overlap the second active layer 220. The second gate electrode 240 overlaps the second channel portion 221 of the second active layer 220.

According to one embodiment of the present disclosure, the second thin film transistor T2 may include a second source electrode 271 and a second drain electrode 272. As shown in FIG. 1, the second source electrode 271 and the second drain electrode 272 may be disposed on the second gate insulating layer 230, for example, but one embodiment of the present disclosure is not limited thereto. The second source electrode 271 and the second drain electrode 272 may be disposed on a different layer from the second gate electrode 240. For example, a separate insulating layer may be disposed on the second gate electrode 240, and the second source electrode 271 and the second drain electrode 272 may be disposed on a separate insulating layer.

The second source electrode 271 and the second drain electrode 272 may be spaced apart from each other and respectively connected to the second active layer 220. Referring to FIG. 1, the second source electrode 271 and the second drain electrode 272 may be connected to the second active layer 220 through a contact hole, respectively.

Each of the second source electrode 271 and the second drain electrode 272 may include at least one of molybdenum (Mo), aluminum (Al), chromium (Cr), gold (Au), titanium (Ti), nickel (Ni), neodymium (Nd), copper (Cu) or their alloy.

In one embodiment and the drawings of the present disclosure, the second source electrode 271 and the second drain electrode 272 are only distinguished for convenience of description, and the second source electrode 271 and the second drain electrode 272 are not limited by the drawings and the aforementioned descriptions. The second source electrode 271 and the second drain electrode 272 may be interchanged. The second source connection portion 222 and the second drain connection portion 223 are also distinguished for convenience of description, and the second source connection portion 222 and the second drain connection portion 223 may be interchanged.

According to one embodiment of the present disclosure, a portion of the second active layer, which is connected to the second source electrode 271, will be referred to as the second source connection portion 222 and a portion of the second active layer, which is connected to the second drain electrode 272, will be referred to as the second drain connection portion 223.

In general, the insulating layers disposed between the second active layer 220 and the base substrate 110 may include hydrogen. For example, the first gate insulating layer 130 and the interlayer insulating layer 150, which are shown in FIG. 1, may include hydrogen. In particular, the interlayer insulating layer 150 includes hydrogen. Hydrogen included in the interlayer insulating layer 150 may move to the second active layer 220 and then is combined with oxygen of the second active layer 220 to cause conductorization of the second active layer 220. In more detail, when hydrogen included in the interlayer insulating layer 150 moves to the second channel portion 221 of the second active layer 220 to conductorize the second channel portion 221, driving stability and reliability of the second thin film transistor T2 may deteriorate. For example, when the second channel portion 221 is contaminated or damaged by hydrogen, a threshold voltage Vth of the second thin film transistor T2 may be shifted in a negative (−) direction, whereby driving stability of the second thin film transistor T2 may deteriorate.

According to one embodiment of the present disclosure, the first protective pattern 161 is disposed to prevent or reduce diffusion of hydrogen included in the insulating layers 130 and 150, which are disposed between the base substrate 110 and the passivation layer 180 supporting the second active layer 220, to the second channel portion 221.

According to one embodiment of the present disclosure, the first protective pattern 161 may be disposed between the base substrate 110 and the second thin film transistor T2. In detail, the first protective pattern 161 may be disposed between the first gate electrode 140 and the second thin film transistor T2.

As shown in FIG. 1, when the first protective pattern 161 is disposed on any one layer between the first active layer 120 of the first thin film transistor T1 and the second active layer 220 of the second thin film transistor T2, the first protective pattern 161 is defined as being disposed between the first thin film transistor T1 and the second thin film transistor T2.

According to one embodiment of the present disclosure, the first protective pattern 161 overlaps the second channel portion 221, and may cover the entire second channel portion 221 on a plane. Since the first protective pattern 161 is designed to cover the entire second channel portion 221, it is possible to stably block hydrogen included in an insulating layer disposed between the first protective pattern 161 and the base substrate 110 from being diffused to the second channel portion 221.

According to one embodiment of the present disclosure, the first protective pattern 161 may overlap the entire second channel portion 221 and at the same time overlap a portion of the second source connection portion 222 and a portion of the second drain connection portion 223.

In detail, the first protective pattern 161 may overlap at least a portion of the second source connection portion 222 and the second drain connection portion 223. FIG. 1 illustrates a configuration in which the first protective pattern 161 overlaps at least a portion of the second source connection portion 222 and the second drain connection portion 223, but one embodiment of the present disclosure is not limited thereto. The first protective pattern 161 may not overlap the second source connection portion 222 and the second drain connection portion 223.

Referring to FIG. 1, the first protective pattern 161 may overlap the first gate electrode 140. In this case, the first protective pattern 161 may overlap the first gate electrode 140 and at the same time overlap the second channel portion 221. In more detail, the first channel portion 121, the first gate electrode 140, the first protective pattern 161, the second channel portion 221 and the second gate electrode 240 may be disposed to overlap one another.

According to one embodiment of the present disclosure, the first protective pattern 161 is disposed to be spaced apart from at least one of the first source electrode 171 or the first drain electrode 172. In detail, FIG. 1 illustrates a configuration in which the first protective pattern 161 is disposed to be spaced apart from the first source electrode 171 and the first drain electrode 172.

According to one embodiment of the present disclosure, the first protective pattern 161 may include silicon nitride. According to one embodiment of the present disclosure, the first protective pattern 161 may be made of silicon nitride represented by SiNx.

In detail, the first protective pattern may include a silicon nitride layer. For example, NH₃ and SiH₄ gases may be used to form the silicon nitride layer. At this time, the silicon nitride layer may be formed by adjusting a ratio of the gases. The silicon nitride layer includes a dangling bond existing on a silicon surface, and the dangling bond may be bonded with hydrogen. As a result, the silicon nitride layer may serve to block hydrogen by collecting hydrogen.

In detail, the dangling bond refers to an incomplete bond in which atoms existing on the surface are not completely bonded. For example, when oxygen or nitrogen is not completely bonded to silicon atoms, an unbonded orbital is generated and this incomplete bond is called a dangling bond.

The first protective pattern 161 serves as a barrier for blocking movement of hydrogen. According to one embodiment of the present disclosure, the first protective pattern 161 is not disposed on the entire surface of the interlayer insulating layer 150 but is patterned to be disposed on a portion of the interlayer insulating layer 150. In detail, the first protective pattern 161 covers the second channel portion 221 to protect the second channel portion 221, and is patterned in a predetermined shape to make sure of a hydrogen discharge passage.

For example, when the first protective pattern 161 is disposed on the entire surface of the interlayer insulating layer 150, hydrogen existing in the insulating layers 130 and 150 disposed between the first protective pattern 161 and the base substrate 110 cannot escape upward and thus hydrogen may not be properly removed. Thus, hydrogen remaining in the insulating layers disposed between the first protective pattern 161 and the base substrate 110 gives the first channel portion 121 more conductivity than necessary, so that the threshold voltage Vth of the first thin film transistor T1 is shifted in the negative (−) direction. As a result, driving stability of the first thin film transistor T1 may deteriorate.

In addition, when the first protective pattern 161 does not exist, hydrogen generated from the insulating layers 130 and 150 disposed between the first protective pattern 161 and the base substrate 110 gives the second channel portion 221 more conductivity than necessary, so that a threshold voltage Vth of the second thin film transistor T2 may be shifted in the negative (−) direction. As a result, driving stability of the second thin film transistor T2 may deteriorate.

As described above, the first protective pattern 161 may overlap the second channel portion and may be patterned so as not to cover the entire surface of the interlayer insulating layer 150, thereby making sure of driving stability and reliability of the first thin film transistor T1 and the second thin film transistor T2 at the same time.

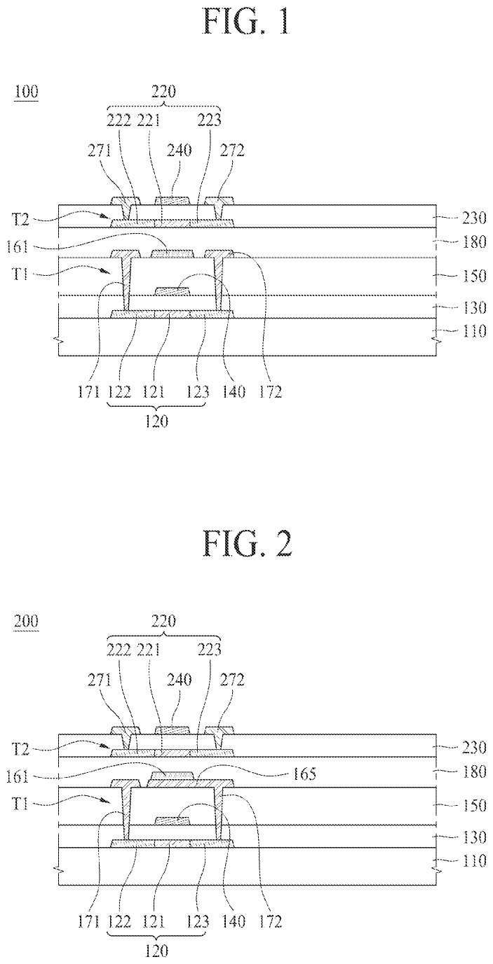

FIG. 2 is a cross-sectional view illustrating a thin film transistor substrate 200 according to another embodiment of the present disclosure. In order to avoid redundancy, descriptions of the already described elements will be omitted.

The thin film transistor substrate 200 shown in FIG. 2 further includes a light shielding pattern 165 as compared with the thin film transistor substrate 100 shown in FIG. 1.

The light shielding pattern 165 may serve as a light shielding layer. The light shielding pattern 165 shields light from the outside to protect the second active layer 220 of the second thin film transistor T2.

According to one embodiment of the present disclosure, the light shielding pattern 165 may be disposed between the first gate electrode 140 and the second active layer 220. Referring to FIG. 2, the light shielding pattern 165 may be disposed on the same layer as at least one of the first source electrode 171 or the first drain electrode 172.

In more detail, according to another embodiment of the present disclosure, the light shielding pattern 165 may be connected to any one of the first source electrode 171 and the first drain electrode 172.

In more detail, according to another embodiment of the present disclosure, the light shielding pattern 165 is integrally formed with any one of the first source electrode 171 and the first drain electrode 172. FIG. 2 illustrates a configuration in which the light shielding pattern 165 is integrally formed with the first drain electrode 172, but one embodiment of the present disclosure is not limited thereto. The light shielding pattern 165 may be integrally formed with the first source electrode 171.

In general, the light shielding pattern 165 may be made of an electrically conductive material such as metal. Thus, the passivation layer 180 is disposed on the light shielding pattern 165 to insulate the light shielding pattern 165 from the second active layer 220.

According to one embodiment of the present disclosure, the first protective pattern 161 may be disposed on the light shielding pattern 165.

In detail, according to another embodiment of the present disclosure, the first protective pattern 161 may be in contact with the light shielding pattern 165.

Referring to FIG. 2, the light shielding pattern 165 may overlap the first channel portion 121. In more detail, the first channel portion 121, the first gate electrode 140, the light shielding pattern 165, the first protective pattern 161 and the second channel portion 221 may overlap one another.

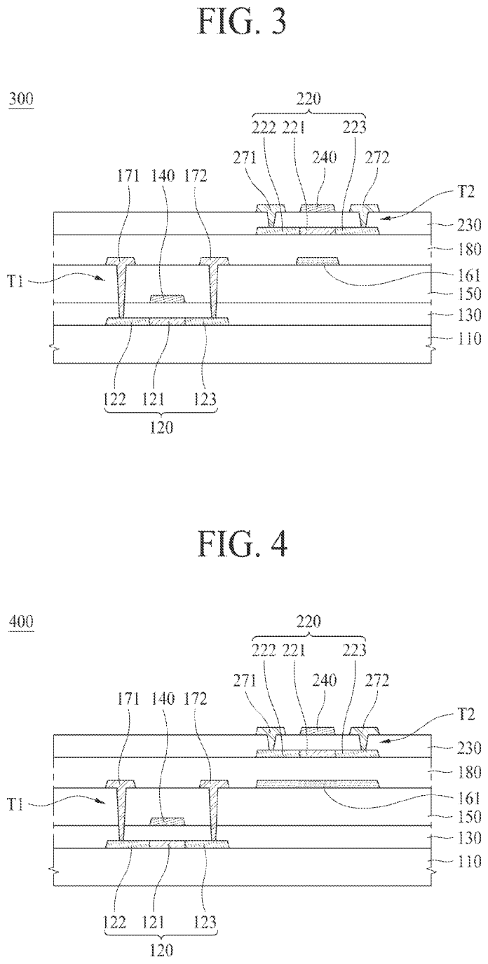

FIG. 3 is a cross-sectional view illustrating a thin film transistor substrate 300 according to still another embodiment of the present disclosure.

In the thin film transistor substrate 300 shown in FIG. 3 as compared with the thin film transistor substrate 100 shown in FIG. 1, the first thin film transistor T1 and the second thin film transistor T2 are spaced apart from each other. In detail, the first active layer 120 and the second active layer 220 may be spaced apart from each other so as not to overlap each other.

According to one embodiment of the present disclosure, the first protective pattern 161 may not overlap the first gate electrode 140.

FIG. 4 is a cross-sectional view illustrating a thin film transistor substrate 400 according to another embodiment of the present disclosure.

In FIG. 4 as compared with FIG. 3, the first protective pattern 161 overlaps the entire second active layer 220, but one embodiment of the present disclosure is not limited thereto. The first protective pattern 161 may not overlap at least a portion of the second source connection portion 222 and the second drain connection portion 223.

FIG. 5 is a cross-sectional view illustrating a thin film transistor substrate 500 according to further still another embodiment of the present disclosure.

The thin film transistor substrate 500 shown in FIG. 5 further includes a light shielding pattern 165 as compared with the thin film transistor substrate 300 shown in FIG. 3.

According to further still another embodiment of the present disclosure, the light shielding pattern 165 may be spaced apart from the first source electrode 171 and the first drain electrode 172.

Referring to FIG. 5, the light shielding pattern 165 may be spaced apart from the first source electrode 171 and the first drain electrode 172, and the light shielding pattern 165 may be connected to any one of the second source electrode 271 and the second drain electrode 272. In detail, FIG. 5 illustrates a configuration in which the light shielding pattern 165 is spaced apart from the first source electrode 171 and the first drain electrode 172 and is connected to the second drain electrode 272, but the embodiment of the present disclosure is not limited thereto. The light shielding pattern 165 may be connected to the second source electrode 271.

According to further still another embodiment of the present disclosure, the light shielding pattern 165 may not overlap the first channel portion 121.

FIG. 5 illustrates a configuration in which the light shielding pattern 165 does not overlap the first channel portion 121.

Referring to FIG. 5, the light shielding pattern 165 is disposed between the interlayer insulating layer 150 and the first protective pattern 161, and more specifically, the light shielding pattern 165 may be disposed on the same layer as the first source electrode 171 and the first drain electrode 172.

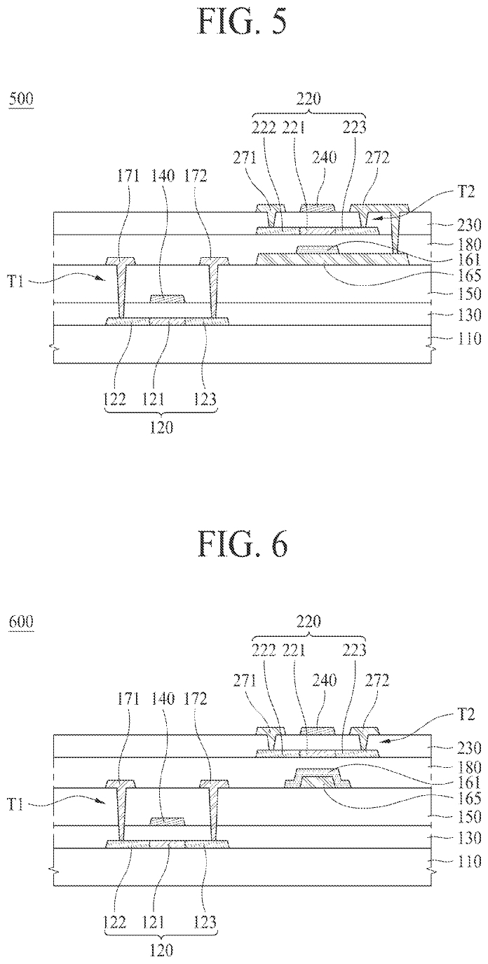

FIG. 6 is a cross-sectional view illustrating a thin film transistor substrate 600 according to further still another embodiment of the present disclosure.

In the thin film transistor substrate 600 shown in FIG. 6 as compared with the thin film transistor substrate 500 shown in FIG. 5, the first protective pattern 161 covers sides of the light shielding pattern 165. In more detail, the first protective pattern 161 may cover an upper surface and the sides of the light shielding pattern 165. Although not shown in FIG. 6, the light shielding pattern 165 may be connected to any one of the second source electrode 271 and the second drain electrode 272.

FIG. 7 is a cross-sectional view illustrating a thin film transistor substrate 700 according to further still another embodiment of the present disclosure.

In the thin film transistor substrate 700 shown in FIG. 7 as compared with the thin film transistor substrate 500 shown in FIG. 5, the light shielding pattern 165 is in contact with the first source electrode 171 and the first drain electrode 172.

According to further still another embodiment of the present disclosure, the light shielding pattern 165 is connected to any one of the first source electrode 171 and the first drain electrode 172.

In more detail, according to further still another embodiment of the present disclosure, the light shielding pattern 165 is integrally formed with any one of the first source electrode 171 and the first drain electrode 172.

For example, FIG. 7 illustrates a configuration in which the light shielding pattern 165 is integrally formed with the first drain electrode 172.

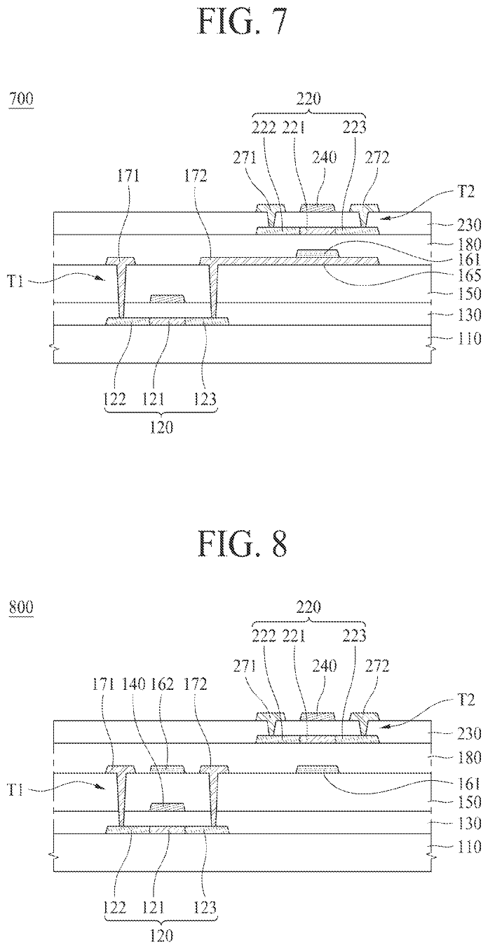

FIG. 8 is a cross-sectional view illustrating a thin film transistor substrate 800 according to further still another embodiment of the present disclosure.

The thin film transistor substrate 800 shown in FIG. 8 further includes a second protective pattern 162 as compared with the thin film transistor substrate 300 shown in FIG. 3.

According to further still another embodiment of the present disclosure, the second protective pattern 162 overlaps the first gate electrode 140. In more detail, the first channel portion 121, the first gate electrode 140 and the second protective pattern 162 may be disposed to overlap one another.

According to further still another embodiment of the present disclosure, the second protective pattern 162 is disposed on the same layer as the first protective pattern 161. In more detail, referring to FIG. 8, the first protective pattern 161, the second protective pattern 162, the first source electrode 171 and the first drain electrode 172 are disposed on the same layer. In more detail, according to one embodiment of the present disclosure, the first protective pattern 161 and the second protective pattern 162 may include the same material.

According to further still another embodiment of the present disclosure, the second protective pattern 162 is spaced apart from the first protective pattern 161.

According to further still another embodiment of the present disclosure, the second protective pattern 162 is disposed to be spaced apart from at least one of the first source electrode 171 or the first drain electrode 172. In detail, FIG. 8 illustrates a configuration in which the second protective pattern 162 is disposed to be spaced apart from the first source electrode 171 and the first drain electrode 172.

According to one embodiment of the present disclosure, the second protective pattern 162 may include silicon nitride. According to one embodiment of the present disclosure, the second protective pattern 162 may be made of silicon nitride represented by SiNx.

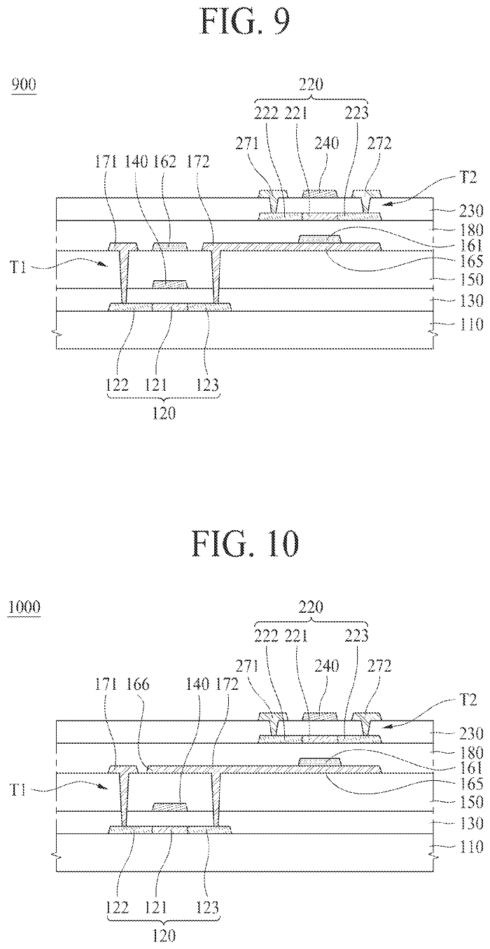

FIG. 9 is a cross-sectional view illustrating a thin film transistor substrate 900 according to further still another embodiment of the present disclosure.

The thin film transistor substrate 900 shown in FIG. 9 further includes a light shielding pattern 165 as compared with the thin film transistor substrate 800 shown in FIG. 8.

The light-shielding pattern 165 may be in contact with any one of the first source electrode 171 and the first drain electrode 172.

FIG. 9 illustrates a configuration in which the light shielding pattern 165 is integrally formed with the first drain electrode 172.

According to further still another embodiment of the present disclosure, the thin film transistor substrate 900 may further include a second protective pattern 162 that is spaced apart from the first source electrode 171 and the first drain electrode 172 yet overlaps the first gate electrode 140. When the light shielding pattern 165 is spaced apart from the first source electrode 171 and the first drain electrode 172, the light shielding pattern 165 may be connected to any one of the second source electrode 271 and the second drain electrode 272.

FIG. 10 is a cross-sectional view illustrating a thin film transistor substrate 1000 according to further still another embodiment of the present disclosure.

As compared with FIG. 7, the thin film transistor substrate 1000 of FIG. 10 further includes a protective layer 166. According to one embodiment of the present disclosure, the protective layer 166 may be connected to any one of the first source electrode 171 and the first drain electrode 172. In detail, FIG. 10 illustrates a configuration in which the protective layer 166 is connected to the first drain electrode 172, but one embodiment of the present disclosure is not limited thereto. The protective layer 166 may be connected to the first source electrode 171.

The protective layer 166 serves as a hydrogen blocking layer for preventing hydrogen introduced from an upper portion of the protective layer 166. In detail, the protective layer 166 may serve as a barrier for protecting the first channel portion 121 from hydrogen above the protective layer 166.

In general, the light shielding pattern 165 may be made of an electrically conductive material such as metal. In detail, the light shielding pattern 165 may include a molybdenum-titanium alloy (MoTi), but one embodiment of the present disclosure is not limited thereto, and may include another metal.

According to one embodiment of the present disclosure, the protective layer 166 may overlap the first channel portion 121.

Although not shown in FIG. 10, according to one embodiment of the present disclosure, the thin film transistor substrate may further include a second protective pattern 162 on the protective layer 166, and the second protective pattern 162 may overlap the first gate electrode 140.

Referring to FIG. 10, an element connected to the first drain connection portion 123 through a contact hole is the first drain electrode 172, an element connected to the first drain electrode 172 to overlap the first gate electrode 140 is the protective layer 166, and an element connected to the first drain electrode 172 to overlap the second active layer 220 is the light shielding pattern 165. At this time, the first drain electrode 172, the protective layer 166 and the light shielding pattern 165 may be integrally formed.

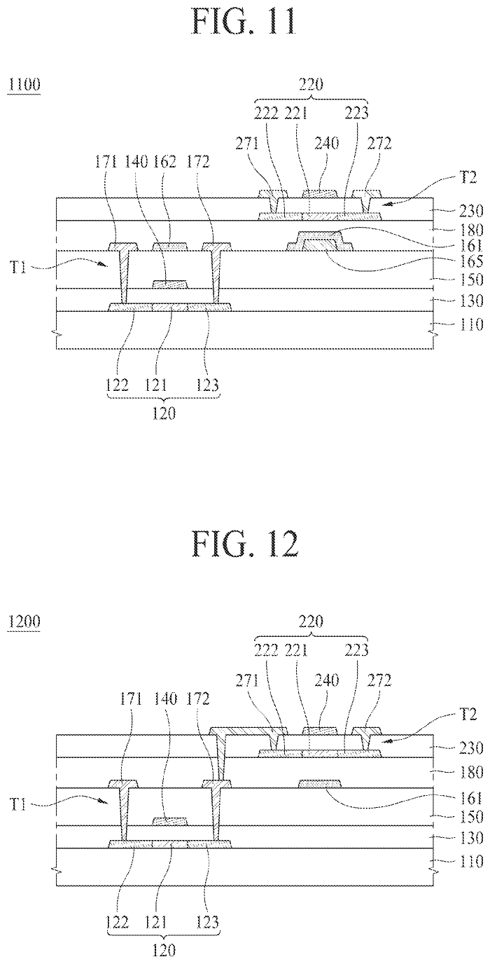

FIG. 11 is a cross-sectional view illustrating a thin film transistor substrate 1100 according to further still another embodiment of the present disclosure.

The thin film transistor substrate 1100 shown in FIG. 11 further includes a second protective pattern as compared with the thin film transistor substrate 600 shown in FIG. 6.

FIG. 12 is a cross-sectional view illustrating a thin film transistor substrate 1200 according to further still another embodiment of the present disclosure.

According to further still another embodiment of the present disclosure, any one of the first source electrode 171 and the first drain electrode 172 may be connected to any one of the second source electrode 271 and the second drain electrode 272.

FIG. 12 illustrates a configuration in which the first drain electrode 172 and the second source electrode 271 are connected through a contact hole. In more detail, the first drain electrode 172 and the second source electrode 271 are connected to the first drain connection portion 123 and the second source connection portion 222 through a contact hole.

In one embodiment and the drawings of the present disclosure, the source electrodes 171 and 271 and the drain electrodes 172 and 272 are only distinguished for convenience of description, and the source electrodes 171 and 271 and the drain electrodes 172 and 272 are not limited by the drawings and the aforementioned descriptions. The source electrodes 171 and 271 and the drain electrodes 172 and 272 may be interchanged.

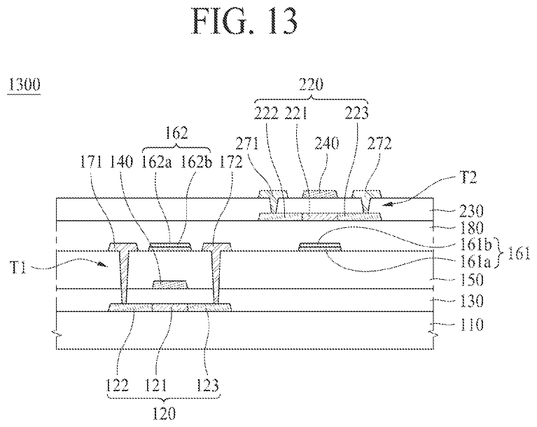

FIG. 13 is a cross-sectional view illustrating a thin film transistor substrate 1300 according to further still another embodiment of the present disclosure.

In the thin film transistor substrate 1300 shown in FIG. 13 as compared with the thin film transistor substrate 800 shown in FIG. 8, at least one of the first protective pattern 161 or the second protective pattern 162 may have a multi-layered structure.

According to one embodiment of the present disclosure, the first protective pattern includes a first layer 161a and a second layer 161b, and the second protective pattern includes a first layer 162a and a second layer 162b.

According to further still another embodiment of the present disclosure, the first protective pattern 161 and the second protective pattern 162 may include first layers 161a and 162a made of silicon nitride (SiNx).

According to further still another embodiment of the present disclosure, the first protective pattern 161 and the second protective pattern 162 may include second layers 161b and 162b made of at least one of a silicon oxide SiOx or a metal oxide. Examples of the metal oxide applicable to the second layers 161b and 162b include, for example, aluminum oxide (Al₂O₃) and hafnium oxide (HfO₂).

A structure in which the first protective pattern 161 and the second protective pattern 162 include the first layers 161a and 162a and the second layers 161b and 162b may be referred to as a bi-layer structure.

FIG. 13 illustrates a configuration in which the first protective pattern 161 and the second protective pattern 162 have a multi-layered structure, and the second layers 161b and 162b are disposed between the first layers 161a and 162a and the second active layer 220. However, the first layers 161a and 162a and the second layers 161b and 162b are not limited by the drawings and the aforementioned descriptions.

According to further still another embodiment of the present disclosure, the second layers 161b and 162b may be disposed between the first layers 161a and 162a and the first active layer 120. In detail, the first layers 161a and 162a may be disposed on the second layers 161b and 162b.

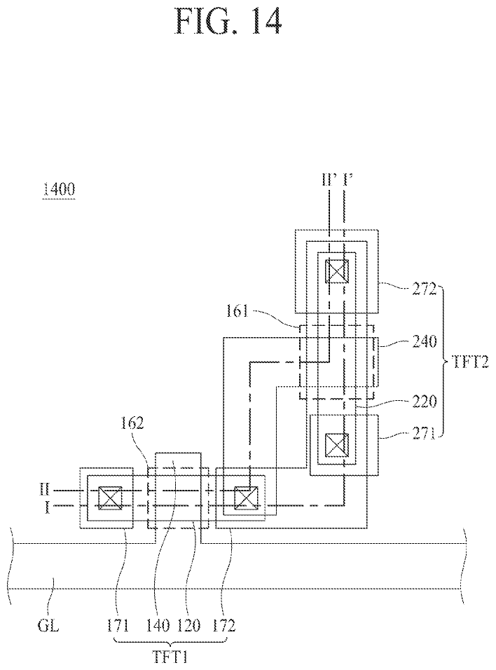

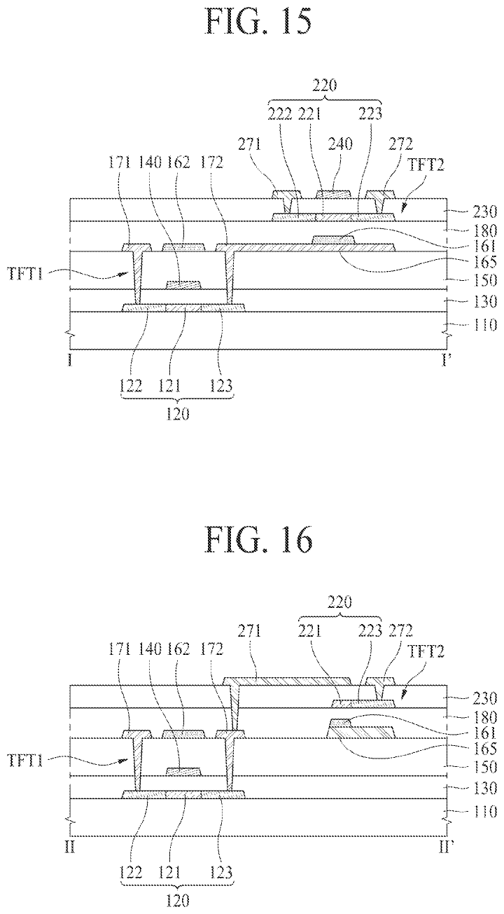

FIG. 14 is a plan view illustrating a portion of a thin film transistor substrate 1400 according to one embodiment of the present disclosure, and FIGS. 14 and 15 are cross-sectional views taken along lines I-I′ and II-II′ of FIG. 14 according to one embodiment of the present disclosure.

Referring to FIGS. 14, 15 and 16, a first thin film transistor TFT1 is disposed on a base substrate 110, and a second thin film transistor TFT2 is disposed on the first thin film transistor TFT1.

Glass or plastic may be used as the base substrate 110. A transparent plastic having a flexible property, for example, polyimide may be used as the base substrate 110.

A first active layer 120 is disposed on the base substrate 110. The first active layer 120 may include an oxide semiconductor material.

In the first thin film transistor TFT1, the first active layer 120 may include a first channel portion 121, a first source connection portion 122 and a first drain connection portion 123. The first channel portion 121 of the first active layer 120 overlaps the first gate electrode 140. The first source connection portion 122 may be referred to as a first source electrode 171, and the first drain connection portion 123 may be referred to as a first drain electrode 172.

A first gate insulating layer 130 is disposed on the first active layer 120. The first gate insulating layer 130 may cover the entire upper surface of the first active layer 120, or may cover only a portion of the first active layer 120.

A first gate electrode 140 is disposed on the first gate insulating layer 130.

The first gate electrode 140 at least partially overlaps the first active layer 120.

An interlayer insulating layer 150 is disposed on the first gate electrode 140

A first protective pattern 161 and a second protective pattern 162 are disposed on the interlayer insulating layer 150.

The first protective pattern 161 and the second protective pattern 162 overlap a second gate electrode 240 and the first gate electrode 140, respectively.

The first source electrode 171 and the first drain electrode 172 are disposed on the interlayer insulating layer 150.

The first source electrode 171 and the first drain electrode 172 may be respectively connected to the first active layer 120 through a contact hole.

In addition, the first drain electrode 172 is extended to form a light shielding pattern 165.

The light shielding pattern 165 protects the second thin film transistor TFT2 by shielding light incident from the outside.

The first protective pattern 161 is disposed on the light shielding pattern 165. In more detail, the light shielding pattern 165 is disposed between the first protective pattern 161 and the interlayer insulating layer 150, but one embodiment of the present disclosure is not limited thereto, and the second protective pattern 162 may be disposed on the light shielding pattern 165.

The first protective pattern 161 overlaps a second channel portion 221, and covers the entire second channel portion 221 on a plane.

The first protective pattern 161 is disposed to be spaced apart from the second protective pattern 162, and is disposed on the same layer as the second protective pattern 162.

A passivation layer 180 is disposed on the first protective pattern 161.

A second active layer 220 is disposed on the passivation layer 180. The second active layer 220 may include an oxide semiconductor material.

In the second thin film transistor TFT2, the second active layer 220 may include a second channel portion 221, a second source connection portion 222 and a second drain connection portion 223. The second channel portion 221 of the second active layer 220 overlaps the second gate electrode 240. The second source connection portion 222 may be referred to as a second source electrode 271, and the second drain connection portion 223 may be referred to as a second drain electrode 272.

A second gate insulating layer 230 is disposed on the second active layer 220.

The second gate electrode 240 is disposed on the second gate insulating layer 230.

The second gate electrode 240 may be connected to the first drain electrode 172 through a contact hole.

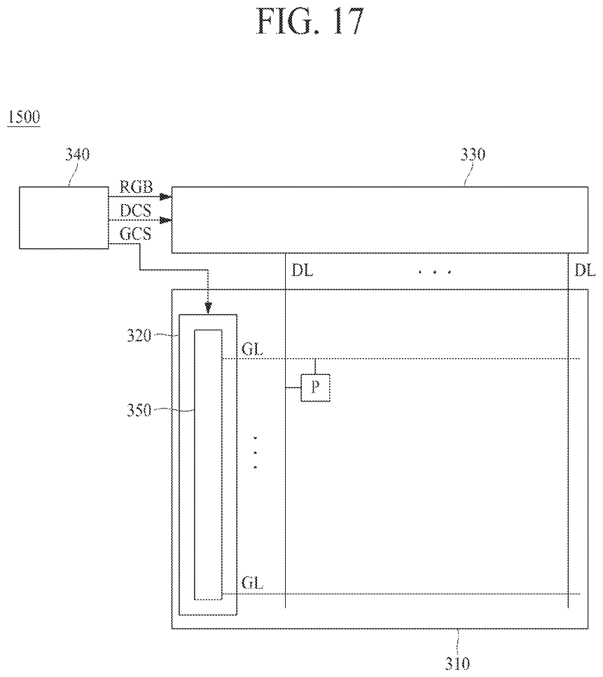

FIGS. 14 and 16 illustrate a configuration in which the second gate electrode 240 is connected to the first drain electrode 172 through a contact hole.

FIG. 17 is a schematic view illustrating a display apparatus 1500 according to further still another embodiment of the present disclosure.

As shown in FIG. 17, the display apparatus 1500 according to further still another embodiment of the present disclosure may include a display panel 310, a gate driver 320, a data driver 330 and a controller 340.

The display panel 310 includes gate lines GL and data lines DL, and pixels P are disposed in intersection areas between the gate lines GL and the data lines DL. An image is displayed by driving of the pixel P. The gate lines GL, the data lines DL and the pixel P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using signals supplied from an external system (not shown). Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 to an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In the Gate In Panel (GIP) structure, the gate driver 320 may be disposed on the base substrate 110.

The display apparatus 1500 according to one embodiment of the present disclosure may include the above-described thin film transistor substrates 100, 200, 300, 400, 500, 600, 700, 800, 900, 1000 and 1100. According to one embodiment of the present disclosure, the gate driver 320 may include the first thin film transistor T1 and the second thin film transistor T2 of the above-described thin film transistor substrates 100, 200, 300, 400, 500, 600, 700, 800, 900, 1000 and 1100.

The gate driver 320 may include a shift register 350.

The shift register 350 sequentially supplies gate pulses to the gate lines GL for one frame by using the start signal and the gate clock, which are transmitted from the controller 340. In this case, one frame means a period at which one image is output through the display panel 310. The gate pulse has a turn-on voltage for turning on a switching element thin film transistor disposed in the pixel P.

Also, the shift register 350 supplies a gate-off signal capable of turning off a switching element, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistor substrates 100, 200, 300, 400, 500, 600, 700, 800, 900, 1000 and 1100.

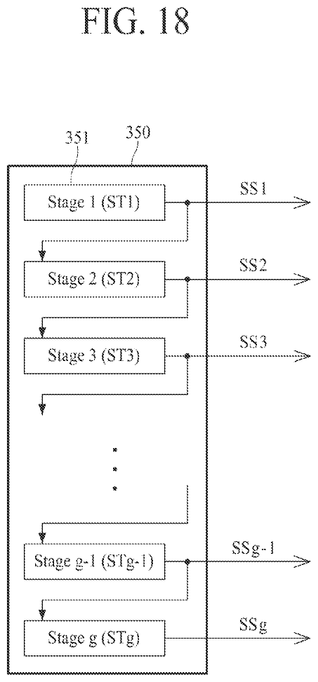

FIG. 18 is a schematic view illustrating a shift register 350 according to one embodiment of the present disclosure.

Referring to FIG. 18, the shift register 350 may include g number of stages 351 (ST1 to STg).

The shift register 350 transmits one scan signal SS to pixels P connected to one gate line GL through one gate line GL. Each of the stages 351 may be connected to one gate line GL. When g number of gate lines GL are formed in the display panel 310, the shift register 350 may include g number of stages 351 (ST1 to STg), and may generate g number of scan signals SS1 to SSg.

In general, each stage 351 outputs the gate pulse GP once during one frame, and the gate pulses GP are sequentially output from each stage 351.

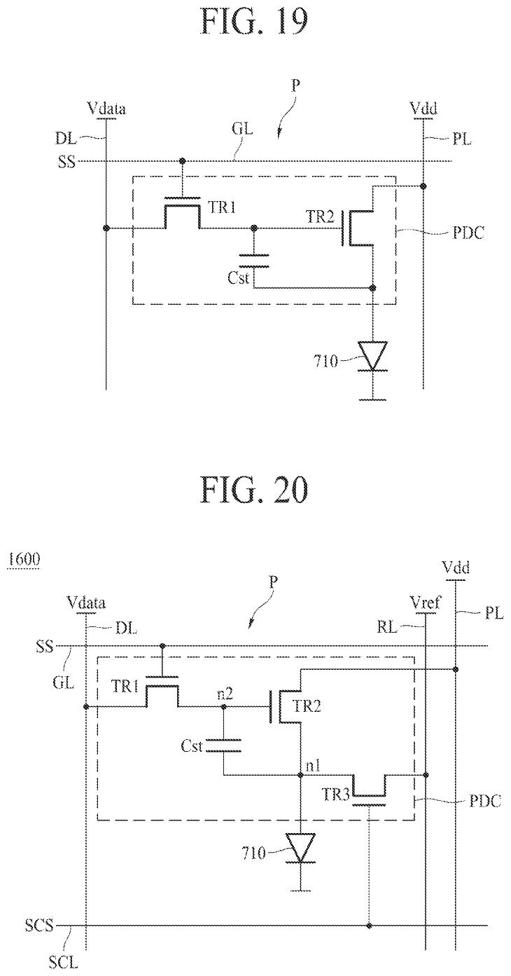

FIG. 19 is a circuit view illustrating any one pixel P of FIG. 17 according to one embodiment of the present disclosure.

The circuit view of FIG. 19 is an equivalent circuit view for the pixel P of the display apparatus 1500 that includes an organic light emitting diode (OLED) as a display device 710.

Referring to FIG. 19, the pixel P includes a display device 710 and a pixel driving circuit PDC for driving the display device 710. In detail, the display apparatus 1500 according to one embodiment of the present disclosure may include a pixel driving circuit PDC on the base substrate 110.

The pixel driving circuit PDC of FIG. 19 includes a first thin film transistor TR1 that is a switching transistor and a second thin film transistor TR2 that is a driving transistor.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display device 710, and the first thin film transistor TR1 controls the driving voltage Vdd. The driving voltage Vdd is a pixel driving voltage for driving the organic light emitting diode (OLED) that is the display device 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display device 710. The data voltage Vdata is charged in a storage capacitor Cst formed between the gate electrode and a source electrode of the second thin film transistor TR2.

The amount of a current supplied to the organic light emitting diode (OLED), which is the display device 710, through the second thin film transistor TR2 is controlled in accordance with the data voltage Vdata, whereby a gray scale of light output from the display device 710 may be controlled.

In the circuit view for any one pixel P of the display apparatus 1500 according to further still another embodiment of the present disclosure, which is shown in FIG. 19, the first thin film transistor TFT1 of FIGS. 13 and 14 corresponds to the first thin film transistor TR1 of FIG. 19, and the second thin film transistor TFT2 corresponds to the second thin film transistor TR2, as compared with the thin film transistor substrates 1300 and 1400 shown in FIGS. 13 and 14.

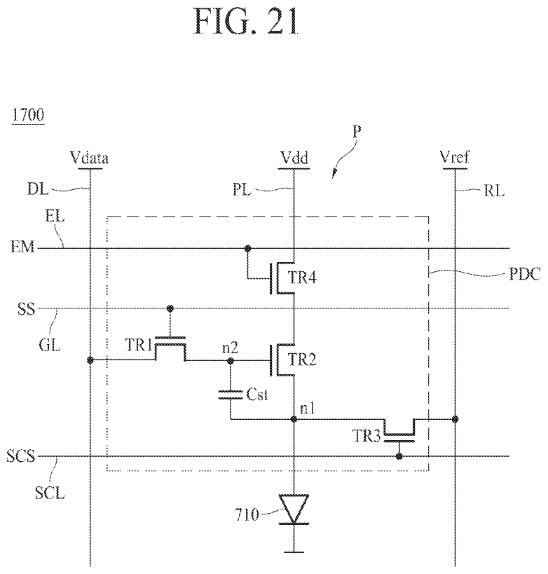

FIG. 20 is a circuit view illustrating any one pixel P of a display apparatus 1600 according to further still another embodiment of the present disclosure.

FIG. 20 is an equivalent circuit view for the pixel P of an organic light emitting display apparatus.

The pixel P of the display apparatus 1600 shown in FIG. 20 includes an organic light emitting diode (OLED) that is a display device 710 and a pixel driving circuit PDC for driving the display device 710. The display device 710 is connected with the pixel driving circuit PDC.

In the pixel P, signal lines DL, GL, PL, RL and SCL for supplying a signal to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

The pixel driving circuit PDC includes, for example, a first thin film transistor TR1 (switching transistor) connected with the gate line GL and the data line DL, a second thin film transistor TR2 (driving transistor) for controlling a magnitude of a current output to the display device 710 in accordance with the data voltage Vdata transmitted through the first thin film transistor TR1, and a third thin film transistor TR3 (sensing transistor) for sensing characteristics of the second thin film transistor TR2.

The first thin film transistor TR1 is turned on by the scan signal SS supplied to the gate line GL to transmit the data voltage Vdata, which is supplied to the data line DL, to the gate electrode of the second thin film transistor TR2.

The third thin film transistor TR3 is connected to a first node n1 between the second thin film transistor TR2 and the display device 710 and the reference line RL, and thus is turned on or off by the sensing control signal SCS and senses characteristics of the second thin film transistor TR2, which is a driving transistor, for a sensing period.

A second node n2 connected with the gate electrode of the second thin film transistor TR2 is connected with the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2.

When the second thin film transistor TR2 is turned on, the current is supplied to the display device 710 through the second thin film transistor TR2 in accordance with the driving voltage Vdd for driving the pixel, whereby light is output from the display device 710.

In the circuit view for any one pixel P of the display apparatus 1600 according to further still another embodiment of the present disclosure, which is shown in FIG. 20, the first thin film transistor T1 corresponds to the third thin film transistor TR3, and the second thin film transistor T2 corresponds to the second thin film transistor TR2, as compared with the thin film transistor substrate 1200 shown in FIG. 12.

Also, in the circuit view for any one pixel P of the display apparatus 1600 according to further still another embodiment of the present disclosure, which is shown in FIG. 20, the first thin film transistor TFT1 of FIGS. 13 and 14 corresponds to the first thin film transistor TR1 of FIG. 20, and the second thin film transistor TFT2 of FIGS. 13 and 14 corresponds to the second thin film transistor TR2 of FIG. 20, as compared with the thin film transistor substrates 1300 and 1400 shown in FIGS. 13 and 14.

FIG. 21 is a circuit view illustrating any one pixel P of a display apparatus 1700 according to further still another embodiment of the present disclosure.

The pixel P of the display apparatus 1700 shown in FIG. 21 includes an organic light emitting diode (OLED) that is a display device 710 and a pixel driving circuit PDC for driving the display device 710. The display device 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 20, the pixel P of FIG. 21 further includes an emission control line EL. An emission control signal EM is supplied to the emission control line EL. Also, the pixel driving circuit PDC of FIG. 21 further includes a fourth thin film transistor TR4 that is an emission control transistor for controlling a light emission timing of the second thin film transistor TR2, in comparison with the pixel driving circuit PDC of FIG. 20.

The first thin film transistor TR1 is turned on by the scan signal SS supplied to the gate line GL to transmit the data voltage Vdata, which is supplied to the data line DL, to the gate electrode of the second thin film transistor TR2.

A storage capacitor Cst is positioned between the gate electrode of the second thin film transistor TR2 and the display device 710.

The third thin film transistor TR3 is connected to the reference line RL, and thus is turned on or off by the sensing control signal SCS and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM or shields the driving voltage Vdd. When the fourth thin film transistor TR4 is turned on, a current is supplied to the second thin film transistor TR2, whereby light is output from the display device 710.

The pixel driving circuit PDC according to further still another embodiment of the present disclosure may be formed in various structures in addition to the above-described structure. The pixel driving circuit PDC may include, for example, five or more thin film transistors.

According to the present disclosure, the following advantageous effects may be obtained.

Since the thin film transistor substrate according to one embodiment of the present disclosure includes the protective pattern having hydrogen blocking characteristics, hydrogen may be prevented or suppressed from being diffused or permeated into the active layer.

The display apparatus according to one embodiment of the present disclosure, which includes the thin film transistor substrate, may have excellent reliability.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor substrate comprising:
a first thin film transistor on a base substrate;
a second thin film transistor on the first thin film transistor; and
a first protective pattern between the first thin film transistor and the second thin film transistor,
wherein the first thin film transistor includes:
a first active layer on the base substrate; and
a first gate electrode spaced apart from the first active layer, the first active layer including a first channel portion that overlaps the first gate electrode,
wherein the second thin film transistor includes:
a second active layer on the base substrate; and
a second gate electrode spaced apart from the second active layer,
wherein the second active layer includes:
a second channel portion that overlaps the second gate electrode;
a second source connection portion connected to one side of the second channel portion; and
a second drain connection portion connected to another side of the second channel portion, the first protective pattern overlapping the second channel portion and covers an entire second channel portion on a plane.

2. The thin film transistor substrate of claim 1, wherein the first protective pattern overlaps at least a portion of the second source connection portion and the second drain connection portion.

3. The thin film transistor substrate of claim 2, wherein the first protective pattern overlaps an entire second active layer.

4. The thin film transistor substrate of claim 1, wherein the first protective pattern overlaps the first gate electrode.

5. The thin film transistor substrate of claim 1, wherein the first protective pattern does not overlap the first gate electrode.

6. The thin film transistor substrate of claim 5, further comprising a second protective pattern that overlaps the first gate electrode.

7. The thin film transistor substrate of claim 6, wherein the second protective pattern is spaced apart from the first protective pattern.

8. The thin film transistor substrate of claim 7, wherein the first protective pattern and the second protective pattern include a same material.

9. The thin film transistor substrate of claim 7, wherein the first thin film transistor includes a first source electrode and a first drain electrode, which are spaced apart from each other and connected to the first active layer, and
each of the first protective pattern and the second protective pattern is spaced apart from at least one of the first source electrode or the first drain electrode.

10. The thin film transistor substrate of claim 1, further comprising a light shielding pattern that overlaps the second channel portion,
wherein the light shielding pattern is between the first gate electrode and the second active layer, and
the first protective pattern is on the light shielding pattern.

11. The thin film transistor substrate of claim 10, wherein the light shielding pattern is in contact with the first protective pattern.

12. The thin film transistor substrate of claim 11, wherein the first protective pattern covers sides of the light shielding pattern.

13. The thin film transistor substrate of claim 10, wherein the first thin film transistor includes a first source electrode and a first drain electrode, which are spaced apart from each other and connected to the first active layer, and
the light shielding pattern is on a same layer as at least one of the first source electrode or the first drain electrode.

14. The thin film transistor substrate of claim 13, wherein the light shielding pattern is connected to any one of the first source electrode and the first drain electrode.

15. The thin film transistor substrate of claim 14, wherein the light shielding pattern is integrally formed with any one of the first source electrode and the first drain electrode.

16. The thin film transistor substrate of claim 10, wherein the light shielding pattern is non-overlapping with the first channel portion.

17. The thin film transistor substrate of claim 16, wherein the first thin film transistor includes a first source electrode and a first drain electrode, which are spaced apart from each other and connected to the first active layer,
the second thin film transistor includes a second source electrode and a second drain electrode, which are spaced apart from each other and connected to the second active layer,
the light shielding pattern is spaced apart from the first source electrode and the first drain electrode, and
the light shielding pattern is connected to any one of the second source electrode and the second drain electrode.

18. The thin film transistor substrate of claim 16, wherein the first thin film transistor includes a first source electrode and a first drain electrode, which are spaced apart from each other and connected to the first active layer,
the thin film transistor substrate further comprising a protective layer that overlaps the first channel portion, wherein the protective layer is connected to any one of the first source electrode and the first drain electrode.

19. The thin film transistor substrate of claim 18, further comprising a second protective pattern on the protective layer,
wherein the second protective pattern overlaps the first gate electrode.

20. The thin film transistor substrate of claim 16, further comprising a second protective pattern that overlaps the first gate electrode and is spaced apart from the first protective pattern.

21. The thin film transistor substrate of claim 10, wherein the light shielding pattern overlaps the first channel portion, and
the first protective pattern overlaps the first channel portion.

22. The thin film transistor substrate of claim 1, wherein the first thin film transistor includes a first source electrode and a first drain electrode, which are spaced apart from each other and connected to the first active layer,
the second thin film transistor includes a second source electrode and a second drain electrode, which are spaced apart from each other and connected to the second active layer, and
any one of the first source electrode and the first drain electrode is connected to any one of the second source electrode and the second drain electrode.

23. The thin film transistor substrate of claim 1, wherein at least one of the first active layer and the second active layer includes an oxide semiconductor material.

24. The thin film transistor substrate of claim 1, wherein the first protective pattern includes silicon nitride.

25. The thin film transistor substrate of claim 1, wherein the first protective pattern is a hydrogen blocking layer.

26. The thin film transistor substrate of claim 1, wherein the first protective pattern includes a first layer and a second layer on the first layer,
the first layer includes silicon nitride, and
the second layer includes at least one of silicon oxide (SiOx), aluminum oxide (Al₂O₃) and hafnium oxide (HfO₂).

27. The thin film transistor substrate of claim 6, wherein the second protective pattern includes a first layer and a second layer on the first layer,
the first layer includes silicon nitride, and
the second layer includes at least one of silicon oxide (SiOx), aluminum oxide (Al₂O₃) and hafnium oxide (HfO₂).

28. A display apparatus comprising the thin film transistor substrate of claim 1.

29. The display apparatus of claim 28, further comprising a gate driver on a base substrate included in the thin film transistor substrate,
wherein the gate driver includes a first thin film transistor and a second thin film transistor included in the thin film transistor substrate.

30. The display apparatus of claim 28, further comprising a pixel driving circuit on a base substrate included in the thin film transistor substrate,
wherein the pixel driving circuit includes a first thin film transistor and a second thin film transistor included in the thin film transistor substrate.
